(19) United States
(12) Patent Application Publication
(10) Pub. No.: US 2004/0237894 A1
(43) Pub. Date: Dec. 2, 2004

(54) Apparatus having high gas conductance

(76) Inventors: Jung-Hun Han, Seoul (KR); Young-Suk Lee, Gyeonggi-do (KR); Soon-Bin Jung, Gyeonggi-do (KR); Jeong-Beom Lee, Gyeonggi-do (KR); Chul-Sik Kim, Incheon (KR); Chang-Yeop Jeon, Seoul (KR); Jae-Euk Ko, Seoul (KR); Young-Rok Kim, Daegu (KR); Seong-Eun Sim, Seoul (KR); Yeng-Hyun Lee, Gyeonggi-do (KR); Jin-Hyuk Yoo, Gyeonggi-do (KR); Dae-Bong Kang, Gyeonggi-do (KR)

Correspondence Address: MARGER JOHNSON & McCOLLOM, P.C., 1030 S.W. Morrison Street, Portland, OR, 97205, US

(21) Appl. No.: 10/858,660

(22) Filed: Jun. 1, 2004

(30) Foreign Application Priority Data
May 30, 2003 (KR) 2003-34953
May 11, 2004 (KR) 2004-33124

(51) Int. Cl. C23C 16/00

(52) U.S. Cl. 118/715

(57) ABSTRACT

An apparatus for a semiconductor device includes: a chamber having upper and lower portions, a volume of the lower portion being greater than a volume of the upper portion; a susceptor in the chamber, the susceptor having a substrate on a top surface thereof; an injector injecting process gases into the chamber; a coil unit over the chamber; a radio frequency power supply connected to the coil unit; and an exhaust through the chamber.

The present invention claims the benefit of Korean Patent Applications No. 2003-34953 filed in Korea on May 30, 2003, and No. 2004-33124 filed in Korea on May 11, 2004, which are hereby incorporated by references.

### BACKGROUND OF THE INVENTION

1. Field of the Invention

The present invention relates to an apparatus for a semiconductor device, and more particularly, to an apparatus of depositing a thin film for a semiconductor device.

2. Discussion of the Related Art

In general, a semiconductor device means a large scale integrated circuit (LSI) fabricated by repetition of depositing a thin film on a substrate such as a wafer and patterning the deposited thin film. Recently, as a fabrication technology is developed, a size of the semiconductor device decreases (compactness) and a density of the semiconductor device increases (high density). However, there are several problems to be solved for obtaining the compactness and the high density of the semiconductor device. One of the problems is a void between patterns. As a size of a pattern on a substrate is reduced, a size of a void between patterns is also reduced. Impurities trapped in the void may reduce a reliability of the semiconductor device and may cause break of a metal line during process. To prevent the above drawbacks, the void may be filled with a dielectric material through a gap fill process.

Among various gap fill processes using a dielectric material, a high density plasma chemical vapor deposition (HDPCVD) method has been widely used because reactive materials having a high density is required. In the HDPCVD method, a plasma density is higher than that of a conventional conductively coupled plasma even under a pressure of about several tens mTorr.

FIG. 1 is a schematic cross-sectional view of a high density plasma chemical vapor deposition (HDPCVD) apparatus according to the related art. In FIG. 1, an HDPCVD apparatus includes a chamber 10, a susceptor 20, a gas injector 30, a coil unit 40, and a radio frequency (RF) power supply 50. The chamber has an inner reactive space kept in a vacuum during process. A substrate “W” is loaded on the susceptor 20 connected to an external bias power supply (not shown). The gas injector 30 disposed over the susceptor 20 injects process gases into the chamber 10. The coil unit 40 is disposed on an outer surface of the chamber 10 and the RF power supply 50 supplies an RF power to the coil unit 40. An exhaust 60 for residual gases is formed at a bottom portion of the chamber 10 and is connected to a pump (not shown) through an exhaust line.

Referring to FIG. 1, a deposition process in the HDPCVD apparatus will be illustrated. After a substrate “W” is loaded on the susceptor 20 through a slot valve (not shown) of the chamber 10, a process gas is injected into the chamber 10 through the gas injector 30. After injecting the process gas, an RF power is supplied to the coil unit 40 by the RF power supply 50 and an electromagnetic field is induced by the coil unit 40. The process gas in the chamber 10 is ionized by the electromagnetic field, and then is exited to a plasma state. After a plasma state is obtained in the chamber 10, ions in a plasma state are attracted to the substrate “W” by a bias power supplied to the susceptor 20, thereby forming a thin film on the substrate “W.” During the deposition process, a pump is operated to evacuate residual gases in the chamber 10 through the exhaust 60 continuously.

In order to perform a gap fill process successfully, a high density of gases should be kept in the chamber 10 and a lot of gases should be exhausted from the chamber 10 at the same time. In an HDPCVD apparatus according to the related art, however, it is hard to obtain the above hydromechanical condition. To solve these problems, an apparatus using an exhaust pump having high pumping speed has been suggested.

FIG. 2 is a schematic cross-sectional view of a high density plasma chemical vapor deposition apparatus using an exhaust pump of high pumping speed according to the related art. In FIG. 2, an exhaust pump 80 having high pumping speed is attached to a chamber 10. A susceptor 20 is formed on a sidewall of the chamber 10, thereby forming a lower portion of the chamber 10 as a vacant space. An exhaust valve 70 is formed at a bottom of the chamber 10. During a deposition process, the exhaust valve 70 is slightly opened and the exhaust pump 80 is operated. Accordingly, residual gases in the chamber 10 are exhausted through the exhaust valve 70, a pumping line 82 and an exhaust line 84 by the exhaust pump 80, thereby adjusting gaseous flow in the chamber 10. A gas injector 30 is formed through a top portion of the chamber 10 and an auxiliary gas injector 32 may be formed through the sidewall of the chamber 10 to supply a process gas uniformly.

However, there is a limitation in effective adjustment of gas conductance in the chamber 10 because capability of the HDPCVD apparatus using the exhaust pump 80 entirely depends on the pumping speed. Moreover, since a lower portion of the chamber 10 for the HDPCVD apparatus does not have an enough volume, accumulated residual gases and by-products near the exhaust valve 70 may flow backward by turbulence to contaminate the substrate “W.”

### SUMMARY OF THE INVENTION

Accordingly, the present invention is directed to an apparatus for a semiconductor device that substantially obviates one or more of the problems due to limitations and disadvantages of the related art.

An object of the present invention is to provide an apparatus having high gas conductance where a process time is reduced.

Another object of the present invention is to provide an apparatus having high gas conductance where a gap fill process is improved due to increase of exhausting amount of gases.

Another object of the present invention is to provide an apparatus having high gas conductance where a substrate contamination by residual gases and by-products is prevented.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an apparatus for a semiconductor device includes: a chamber having upper and lower portions, a volume of the lower portion being greater than a volume of the upper portion; a susceptor in the chamber, the susceptor having a substrate on a top surface thereof; an injector injecting process gases into the chamber; a coil unit over the chamber; a radio frequency power supply connected to the coil unit; and an exhaust through the chamber.

In another aspect, an apparatus for a semiconductor device includes: a chamber; a susceptor in the chamber; an injector injecting process gases into the chamber; a coil unit over the chamber; a power supply connected to the coil unit; and an exhaust through the chamber, wherein the chamber is divided into upper and lower portions with a top surface of the susceptor as a reference and a volume of the lower portion is greater than a volume of the lower portion.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic cross-sectional view of a high density plasma chemical vapor deposition (HDPCVD) apparatus according to the related art;

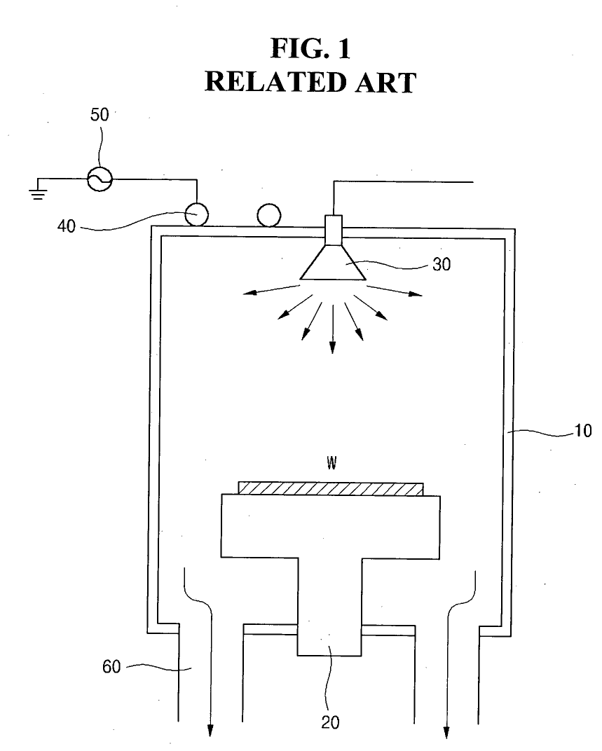

FIG. 2 is a schematic cross-sectional view of a high density plasma chemical vapor deposition apparatus using an exhaust pump of high pumping speed according to the related art;

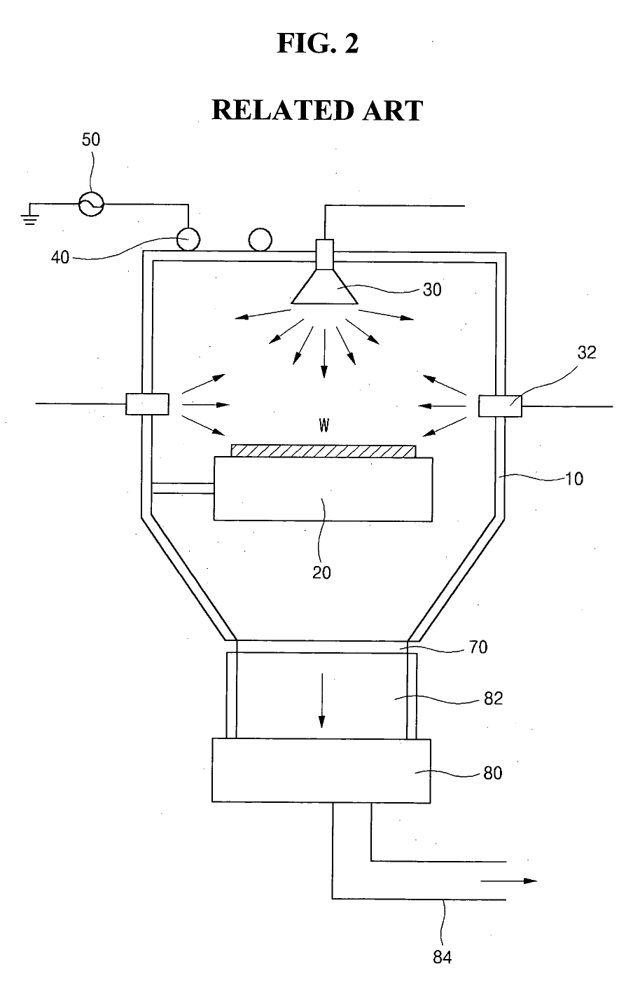

FIG. 3 is a schematic cross-sectional view of a high density plasma chemical vapor deposition apparatus according to an embodiment of the present invention;

FIG. 4 is a schematic cross-sectional view showing an HDPCVD apparatus, where a susceptor is at its highest position, according to an embodiment of the present invention;

FIG. 5 is a schematic cross-sectional view of a high density plasma chemical vapor deposition apparatus according to another embodiment of the present invention; and

FIG. 6 is a schematic cross-sectional view of a high density plasma chemical vapor deposition apparatus according to another embodiment of the present invention.

### DETAILED DESCRIPTION OF THE PREFERRED EMBODIMENTS

Reference will now be made in detail to the preferred embodiments, examples of which are illustrated in the accompanying drawings.

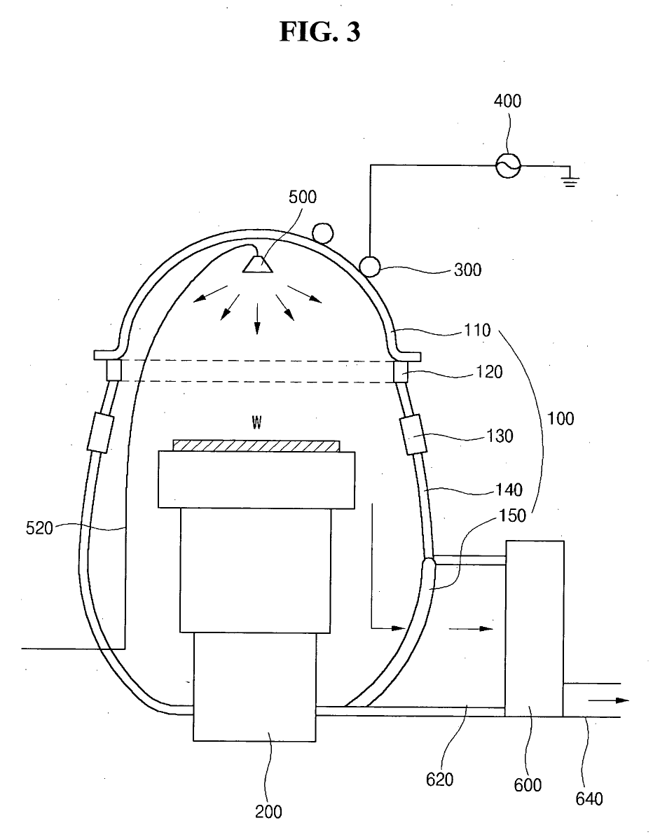

FIG. 3 is a schematic cross-sectional view of a high density plasma chemical vapor deposition apparatus according to an embodiment of the present invention.

In FIG. 3, a HDPCVD apparatus includes a chamber 100, a susceptor 200 and a gas injector 500. The chamber 100 has an inner reactive space and a substrate “W” is loaded on the susceptor 200 formed in the chamber 100. The gas injector 500 disposed over the susceptor 200 injects process gases into the chamber 100.

Specifically, the chamber 100 includes a dielectric dome 110 surrounding the inner reactive space, a chamber body 140 combined to the dielectric dome 110 and a connection unit 120 connecting a lower edge portion of the dielectric dome 110 and an upper edge portion of the chamber body 140. The dielectric dome 110 functions as an energy window transmitting a radio frequency (RF) power through a coil unit 300 at a top portion of the dielectric dome 110. Although the dielectric dome 110 has a round shape in this embodiment, the dielectric dome 110 may have a different shape in another embodiment.

The chamber body 140 is combined to a bottom portion of the dielectric dome 110. The chamber body 140 has a volume greater than a volume of the dielectric dome 110. To increase a volume of the chamber body 140, for example, the chamber body 140 may have a pot shape. A cross-sectional area of the chamber body 140 gradually increases from a top portion near the dielectric dome 110 to a middle portion of the chamber body 140, and then the cross-sectional area of the chamber body 140 gradually decreases from the middle portion to a bottom portion of the chamber body 140. In other words, the cross-sectional area of the chamber body 140 may have a maximum value at a middle portion of the chamber body 140. Although the chamber body 140 has a pot shape in this embodiment, the chamber body 140 may have a various shape different from a pot shape in another embodiment.

The chamber body 140 may be divided into an upper portion and a lower portion with a top surface of the susceptor 200 as a reference. When a volume of the lower portion is greater a volume of the upper portion, a gas conductance increases and a probability that residual gases and by-products flow backward from the lower portion to the upper portion is prevented. Accordingly, a contamination of the substrate “W” is reduced. The gas conductance depends on a flow speed and a flow amount of process gases that flow from the upper portion to the lower portion of the chamber body 140. Thus, the gas conductance increases and a backward flow of particles such as residual gases and by-products is prevented by the chamber body 140 having a lower portion greater than an upper portion and the exhaust pump 200.

Since a plasma is generated in the reactive space of the dielectric dome 110 by the RF power supplied to the coil unit 300, a plasma density has a maximum value in a top portion of the chamber body 140. In addition, deterioration due to particles by turbulence at a bottom portion of the chamber body 140 is minimized at the top portion of the chamber body 140. Accordingly, a process for the substrate “W” may be performed in the top portion of the chamber body 140 and then the substrate “W” may be unloaded near the bottom portion of the chamber body 140. As a result, the susceptor 200 may be formed to move up and down by an external driving unit. When the susceptor 200 is formed to move up and down, the upper and lower portions of the chamber body 140 may be defined using a top surface of the susceptor 200 when the susceptor is at the lowest position as a reference. For example, the chamber body 140 may have a shape such that the cross-sectional area gradually increases along downward movement of the susceptor 200.

The connection unit 120 may have a ring shape to connect the dielectric dome 110 and a top boundary portion of the chamber body 140. The connection unit 120 may have various shapes according to the shapes of the dielectric dome 110 and the chamber body 140 in another embodiment. Moreover, a gap between the dielectric dome 110 and the connection unit 120 and a gap between the connection unit 120 and the chamber body 140 may be sealed with a sealing means such as o-ring to keep an inner space by the dielectric dome 110, the connection unit 120 and the chamber body 140 a vacuum state.

A slot valve 130 through which the substrate “W” is loaded and unloaded may be formed on the sidewall of the chamber body 140. The injector 500 may be disposed at a central portion of the dielectric dome 110 and connected to a gas supply pipe 520 disposed through a lower portion of the sidewall of the chamber body 140. The gas supply pipe 520 may be disposed through a bottom portion of the chamber body 140 in another embodiment.

An exhaust 150 for residual gases and by-products may be formed at a lower portion of the sidewall of the chamber body 140 and an exhaust valve may be formed at the exhaust 150 to close or open the exhaust 150. The exhaust 150 may be connected to a pump 600 through a first exhaust line 620, and the residual gases and by-products may be exhausted to exterior through a second exhaust line 640 connected to the pump 600. For example, a turbo molecular pump (TMP) may be used as the pump 600 for obtaining high gas conductance even under an ultra high vacuum state. In addition, the exhaust 150 may be formed at the lower portion of the sidewall of the chamber body 140 and the first exhaust pipe 620 may be connected to the exhaust 150 horizontally because the susceptor 200 is disposed to penetrate the bottom portion of the chamber body 120. The position of the exhaust 150 may be changed in another embodiment. The first and second exhaust pipes 620 and 640 may have various diameters.

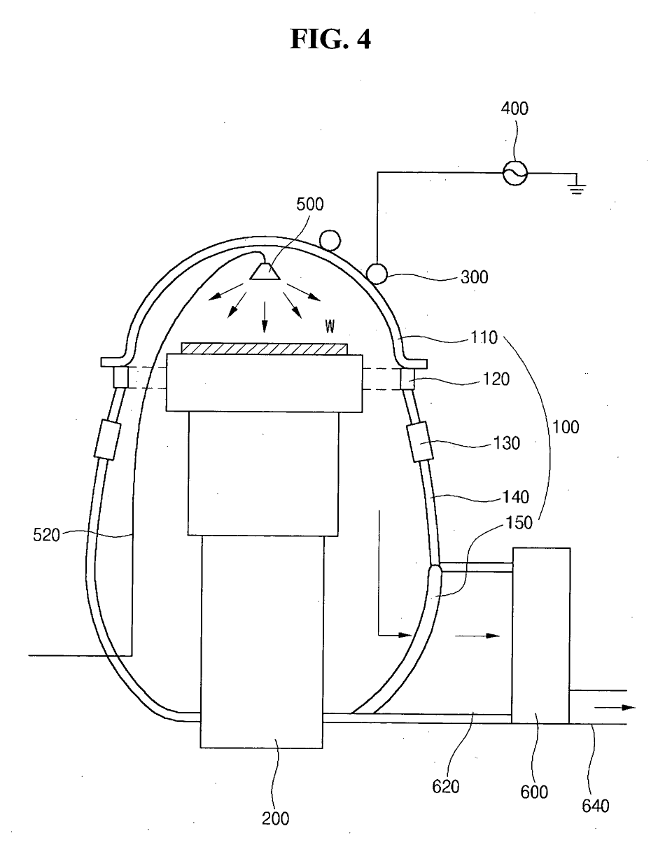

A process in the HDPCVD apparatus of the present invention may be illustrated. After a substrate “W” is loaded on the top surface of the susceptor 200 through the slot valve 130 on the sidewall of the chamber body 140, the susceptor 200 having the substrate “W” thereon moves up to the top portion directly under the reactive space of the dielectric dome 110. FIG. 4 is a schematic cross-sectional view showing an HDPCVD apparatus, where a susceptor is at its highest position, according to an embodiment of the present invention. When the susceptor 200 reaches the top portion, process gases are injected into the dielectric dome 110 through the injector 500. Subsequently, the RF power is supplied to the coil unit 300 by the RF power supply 400 and the coil unit 300 induces an electromagnetic field. The process gases in a space between the dielectric dome 110 and the substrate “W” is ionized by the electromagnetic field to be excited to a plasma state. The ions of plasma are attracted to the substrate “W” on the susceptor 200 by supplying a high frequency bias power to the susceptor 200 to form a thin film on the substrate “W.”

During the process in the HDPCVD apparatus, the pump 600 is operated to evacuate the residual gases and by-products in the chamber 100 through the exhaust 150, the first exhaust pipe 620 and the second exhaust pipe 640 continuously. The chamber body 140 has a pot shape and the chamber 100 also has a pot shape as a whole by combining the dielectric dome 110 to the chamber body 140. A cross-sectional area of the chamber 100 gradually increases from a top portion of the chamber 100 to a middle portion of the chamber 100, and then the cross-sectional area of the chamber 100 gradually decreases from the middle portion of the chamber 100 to a bottom portion of the chamber 100. Accordingly, an amount of the process gases injected into the chamber 100 increases and a flow speed of the residual gases and by-products exhausted from the chamber 100 also increases. In other words, since the chamber body 140 has a volume greater than a volume of the dielectric dome 110, a gas conductance of the process gases increases. Further, when upper and lower portions of the chamber body 140 is defined using a top surface of the susceptor 200 at its lowest position as a reference, the gas conductance further increases by forming the chamber body 140 such that a volume of the lower portion is greater than a volume of the upper portion. Therefore, a gap fill process is improved.

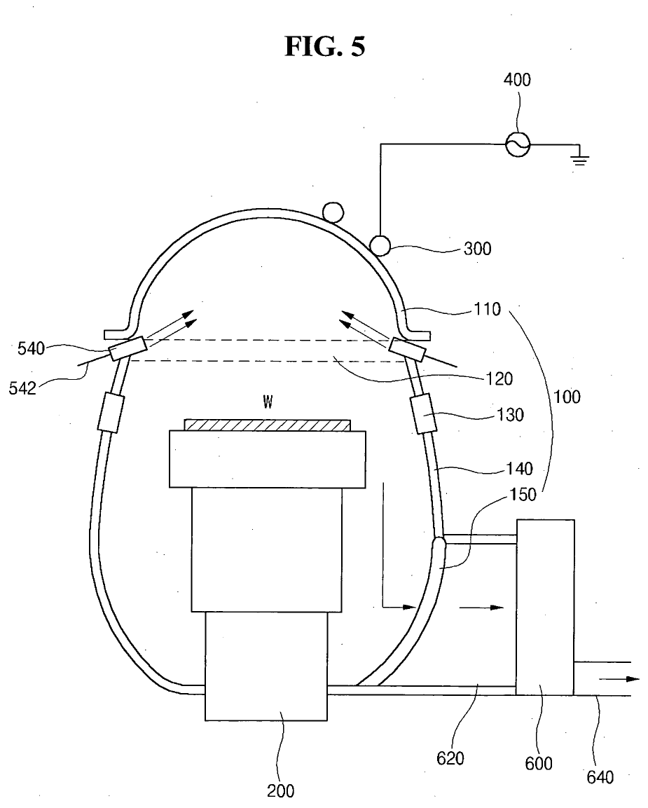

FIG. 5 is a schematic cross-sectional view of a high density plasma chemical vapor deposition apparatus according to another embodiment of the present invention.

In FIG. 5, an injector includes a plurality of sub-injectors 540 disposed on a sidewall of a chamber 100. The plurality of sub-injectors 540 may be disposed symmetrically for uniform distribution of process gases. The process gases may be injected into the chamber 100 through the plurality of sub-injectors 540 horizontally or the process gases may be injected toward a top portion of a dielectric dome 100. The plurality of injectors 540 may be two or at least three. Although the plurality of sub-injectors 540 are disposed at a connection unit 120 in FIG. 5, the plurality of sub-injectors 540 may be disposed at the chamber body 140 in another embodiment. Each of the plurality of sub-injectors 540 may be connected to a gas supply pipe 520.

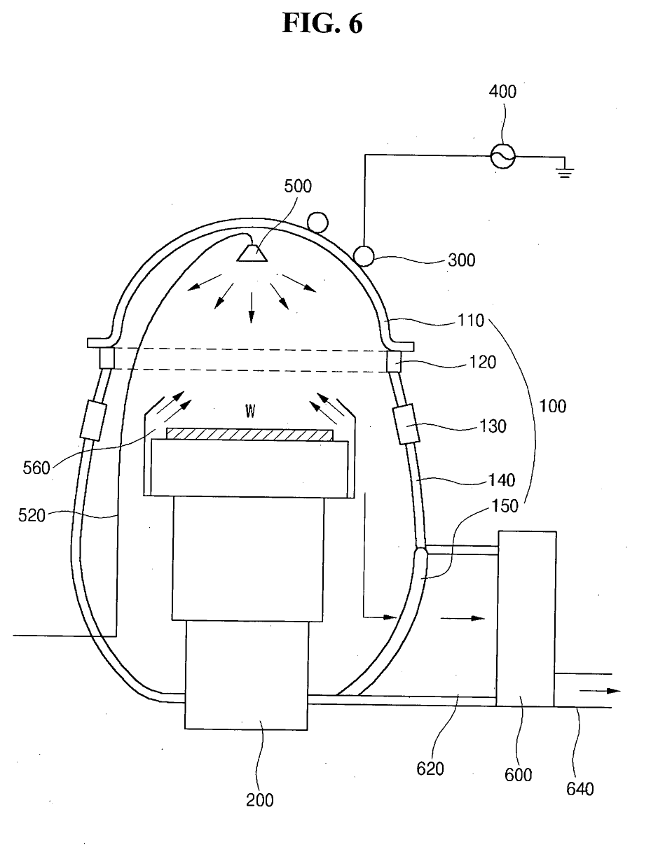

FIG. 6 is a schematic cross-sectional view of a high density plasma chemical vapor deposition apparatus according to another embodiment of the present invention.

In FIG. 6, an injector 500 is disposed at a central portion of a dielectric dome 110 over a susceptor 200 and an auxiliary injector 560 of a ring shape is disposed at a boundary portion of the susceptor 200. The auxiliary injector 560 and the susceptor 200 may be formed as one body. The injector 500 may be connected to a first gas supply pipe 520 and the auxiliary injector 560 may be connected to a second gas supply pipe (not shown) in the susceptor 200. Process gases may be obliquely injected toward a portion over the susceptor 200 to obtain uniform distribution of the process gases over a substrate “W.”

In an HDPCVD apparatus according to the present invention, since a chamber has a pot shape, a high gas conductance of process gases is obtained. Thus, an amount of injected process gases increases and an amount of exhausted residual gases and by-products increases, thereby performing improved gap fill process for a narrower gap. Moreover, since an exhaust pipe is connected to a chamber horizontally, a higher gas conductance is obtained.

It will be apparent to those skilled in the art that various modifications and variations can be made in the apparatus having a high gas conductance without departing from the spirit or scope of the invention. Thus, it is intended that the present invention covers the modifications and variations of this invention provided they come within the scope of the appended claims and their equivalents.

What is claimed is:

1. An apparatus for a semiconductor device, comprising:
a chamber having upper and lower portions, a volume of the lower portion being greater than a volume of the upper portion;
a susceptor in the chamber, the susceptor having a substrate on a top surface thereof;
an injector injecting process gases into the chamber;
a coil unit over the chamber;
a radio frequency power supply connected to the coil unit; and
an exhaust through the chamber.

2. The apparatus according to claim 1, wherein the susceptor moves up and down, thereby having first and second positions corresponding to maximum and minimum heights, respectively.

3. The apparatus according to claim 2, wherein the chamber is divided into first and second portions with the top surface of the susceptor at the second position as a reference and a volume of the second portion is greater than a volume of the first portion.

4. The apparatus according to claim 2, wherein a cross-sectional area of the chamber gradually increases along a direction from the first position to the second position.

5. The apparatus according to claim 1, wherein the chamber includes a dielectric dome and a chamber body connected to the dielectric dome.

6. The apparatus according to claim 5, further comprising a connection unit connecting the dielectric dome and the chamber body.

7. The apparatus according to claim 5, wherein a volume of the chamber body is greater than a volume of the dielectric dome.

8. The apparatus according to claim 5, wherein the chamber body has a top portion, a central portion and a bottom portion and a cross-sectional area of the chamber body at the central portion is greater than cross-sectional areas of the chamber body at the top portion and at the bottom portion.

9. The apparatus according to claim 1, wherein the chamber has a pot shape.

10. The apparatus according to claim 1, wherein the injector is disposed over the susceptor.

11. The apparatus according to claim 10, further comprising an auxiliary injector at a boundary portion of the susceptor, the auxiliary injector having a ring shape.

12. The apparatus according to claim 1, wherein the injector includes a plurality of sub-injectors disposed on a sidewall of the chamber symmetrically.

13. The apparatus according to claim 1, wherein the exhaust is disposed through one of a sidewall and a bottom of the chamber.

14. The apparatus according to claim 1, further comprising a pump connected to the chamber through the exhaust.

15. An apparatus for a semiconductor device, comprising:
a chamber;
a susceptor in the chamber;
an injector injecting process gases into the chamber;
a coil unit over the chamber;
a power supply connected to the coil unit; and
an exhaust through the chamber,
wherein the chamber is divided into upper and lower portions with a top surface of the susceptor as a reference and a volume of the lower portion is greater than a volume of the lower portion.

16. The apparatus according to claim 1, wherein the process gases are injected into the upper portion.
